(19) United States
(12) Patent Application Publication
(10) Pub. No.: US 2014/0007940 A1
(43) Pub. Date: Jan. 9, 2014

(54) LIGHT TRANSMITTING THERMOPLASTIC RESINS COMPRISING DOWN CONVERSION MATERIAL AND THEIR USE IN PHOTOVOLTAIC MODULES

(71) Applicants: Shaofu Wu, Sugar Land, TX (US); Xuming Chen, Pearland, TX (US); Michael A. De Graaf, Middelburg (NL); Steven R. Erskine, Lake Jackson, TX (US); Rebekah K. Feist, Midland, MI (US)

(72) Inventors: Shaofu Wu, Sugar Land, TX (US); Xuming Chen, Pearland, TX (US); Michael A. De Graaf, Middelburg (NL); Steven R. Erskine, Lake Jackson, TX (US); Rebekah K. Feist, Midland, MI (US)

(21) Appl. No.: 14/006,220

(22) PCT Filed: Mar. 23, 2012
(86) PCT No.: PCT/US12/30276

§ 371 Date: Sep. 19, 2013

Related U.S. Application Data
(60) Provisional application No. 61/470,184, filed on Mar. 31, 2011.

(51) Int. Cl. C09K 11/02; H01L 31/055

(52) U.S. Cl. CPC C09K 11/025; H01L 31/055
USPC 136/257; 252/301.35

(57) ABSTRACT

Disclosed are thermoplastic resin formulations for use as a light transmitting layer (e.g., encapsulant layer) in a photovoltaic module comprising: (a) a light transmitting thermoplastic resin, (b) at least one down conversion material that exhibits a maximum in incident radiation absorption in the range of 280 to 500 nm and a maximum in radiation emission at a relatively longer wavelength in the range of 400 to 900 nm and improves the efficiency of photovoltaic electric current generation in a photovoltaic module; and (c) a light stabilizer additive that transmits at least about 40 percent of the ultraviolet (UV) electromagnetic radiation having a wavelength in the range of from about 280 nm to about 380 nm. Also disclosed are sheet materials prepared from such resins and photovoltaic modules incorporating such sheet materials.

This application claims priority from provisional application Ser. No. 61/470,184, filed Mar. 31, 2011, which is incorporated herein by reference in its entirety.

This invention relates to light transmitting thermoplastic resins comprising down conversion material. In another embodiment, it also relates to use of such resins as films or layers in photovoltaic (“PV”) modules. The resins according to this invention provide improved combinations of photovoltaic module durability, energy conversion and cost effectiveness.

As known, photovoltaic modules convert electromagnetic radiation, mainly at or near the visible light spectral range, into electrical energy. Their efficiency in converting light or photons into electrical current is also referred to as “quantum efficiency”. It is known to use a “down conversion” material to attempt to improve photovoltaic modules in the area of spectral response to higher energy, shorter wavelength light by converting shorter wavelength light to longer wavelength. Down conversion materials are typically one or more known organic or inorganic materials that are able to absorb higher energy, short-wavelength light (i.e., in a range where the PV cell exhibits low external quantum efficiency) and re-emit this light at lower energy, longer wavelength (i.e. in a range where the PV cell exhibits a higher external quantum efficiency).

This “down conversion” (sometimes also referred to as “down-shifting”) effect and proposed materials are described, for example in a number of documents including: W0 2007/043496; W0 2009/002943; W0 2009/157879W0 2003/079457; US 2005/0265935; US 2006/0169971; and US 2010/0186801.

As is known, photovoltaic modules are required to withstand long periods of operation (e.g. more than 20 years) with direct exposure to ultraviolet (“UV”) radiation. It is known that selected types of thermoplastic polymer resins can provide a good and cost effective balance of optical, electrical and physical properties, and perform well in many applications but are difficult to employ in the harsh exposure conditions experienced in photovoltaic module applications. When used, many types of thermoplastic polymer resins require stabilizing additives that protect against UV radiation that is known to cause degradation of many types of thermoplastic polymer resins and would otherwise rapidly degrade the polymer properties during extended exposure to UV radiation.

Where UV stabilization is required for a thermoplastic polymer resin, it would be generally expected to block, absorb and/or generally reduce the transmission of the shorter wavelength UV radiation that might otherwise be “down converted” and transmitted as useful radiation to the photovoltaic cell for conversion to electric energy. Such UV stabilized thermoplastic resins, therefore, would not be expected to effectively contain and utilize a down conversion material since UV stabilization would defeat the desired down conversion effect. However, without stabilization, the UV radiation would penetrate at least a finite distance into that layer during down conversion and degrade the polymer.

Thus, it would be desirable to obtain thermoplastic resins and films or layers of such resins that are UV stable, at least partially UV light transmitting and comprise at least one down conversion material, which sheet materials provide good conversion efficiency in a photovoltaic module. It would also be desirable to obtain photovoltaic modules comprising such thermoplastic polymer resin materials and methods for their manufacture. It is therefore an object of the present invention to provide these and other results.

### SUMMARY OF THE INVENTION

One or more of these and various other desirable results are provided according to the present invention which, in one embodiment is a thermoplastic resin formulation for use as a light transmitting layer in a photovoltaic module comprising:

(a) a light transmitting thermoplastic resin,
(b) at least one down conversion material that exhibits a maximum in incident radiation absorption in the range of 280 to 500 nm and a maximum in radiation emission at a relatively longer wavelength in the range of 400 to 900 nm and improves the efficiency of photovoltaic electric current generation in a photovoltaic module; and
(c) a light stabilizer additive that transmits at least about 40 percent of the ultraviolet (UV) electromagnetic radiation having a wavelength in the range of from about 280 nm to about 380 nm.

In other alternative embodiments, the present invention is a thermoplastic resin formulation as described above wherein the down conversion material exhibits a maximum in absorption of electromagnetic radiation within a spectral range from 300 to 500 nanometers, and/or exhibiting a maximum in emission of electromagnetic radiation within a spectral range from 400 to 600 nanometers. In other alternative embodiments, the thermoplastic resin formulations according to the present invention comprise a light stabilizer that is selected from the group consisting of Cyasorb 3346, Cyasorb 3529; Chimassorb 944 LD; Tinuvin 622; Univul 4050; Univul 5050, also Hostavin N30 and Chimassorb 119.

Other alternative embodiments include such thermoplastic resin formulations as otherwise described herein wherein the down conversion material comprises a material selected from:

(a) inorganic nanoparticles selected from:
(i) nanoparticles of compounds containing photoluminescent lanthanide cations selected from the group consisting of: La, Ce, Pr, Eu, Nd, Pm, Sm, Tb, Dy, Ho, Er, Tm and Yb, and
(ii) quantum dots selected from the group of semiconductor nanocrystal compounds that can produce more than one excitons from one high energy photon of sunlight;
   and including composites comprising one or more of the nanoparticles (i) or semiconductor nanocrystal compounds (II) mentioned above having a core-shell structure, the nanoparticles or nanocrystals having a size range of from about 1 nm to about 200 nm; and
   (b) organic luminescent down conversion additives selected from the following and including derivatives thereof: Rhodamine, Coumarin, Rubrene, Alq3, TPD, Gaq2Cl, Perylene dye, Naphthalene carbonic acid, and Violanthrone or iso-violanthrone.

In another alternative embodiment, the present invention is a sheet material for use as a light transmitting layer in a photovoltaic cell comprising a thermoplastic resin formulation selected from those described above.

In a further embodiment, the present invention is a photovoltaic module for the conversion of incident electromagnetic radiation into electric energy, comprising: (i) a light transmitting exterior surface cover sheet; (ii) at least one light transmitting encapsulation sheet material prepared from a thermoplastic resin formulation as described above providing protection to a photovoltaic cell from environmental effects, (iii) a protective exterior surface back sheet and (iv) least one photovoltaic cell adapted to convert into electric energy electromagnetic radiation that has passed through the cover sheet and encapsulation film. In other alternative embodiments the present invention is such a photovoltaic module, wherein the photovoltaic cell comprises at least one of the following materials: CdS; Si; CdTe; InP; GaAs; Cu2S; and Copper Indium Gallium Diselenide (CIGS), Crystalline Silicon (c-Si), amorphous silicon (a-Si), or CIS.

### BRIEF DESCRIPTION OF THE DRAWINGS

FIG. 1 is a graph demonstrating the effect of wavelength “down conversion” by a perylene dye, Lumogen™ M 570 Violet.

FIGS. 2a and 2b are graphs demonstrating for a series of films the percentages of the incident light between the wavelengths of 200 and 400 nanometers that are transmitted through the films.

FIG. 3 is a cross-sectional view of an example structure for a PV module.

### DETAILED DESCRIPTION

### Down Conversion Materials

An important component for preparing thermoplastic polymer resin materials according to the present invention is the suitable electromagnetic radiation down conversion material that absorbs incident radiation having a relatively shorter wavelength and re-emits the radiation at a relatively longer wavelength. There are a number of known organic and inorganic materials and compounds that will be suited for this use; some are also referred to as luminescent materials. In various embodiments of the present invention a single down conversion material may be used or, additionally, a combination or a “chain” of down conversion materials may be used, e.g. in order to provide a down conversion “cascade”.

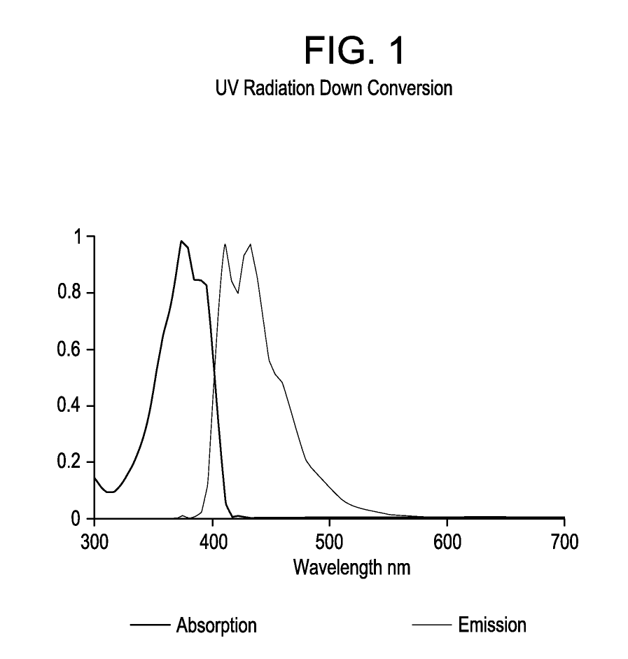

In one embodiment, such down conversion material effectively absorbs electromagnetic energy primarily from radiation within the UV spectral range (of from about 280 to about 400 nanometers (nm)) and emits radiation at a relatively higher wavelength. Desirably, the material has at least one “maximum in absorption” of electromagnetic energy in this range, preferably all such maximums in absorption, in cases where there is more than one. A “maximum in absorption” of a down conversion material refers to the light wavelength out of the solar electromagnetic wave spectrum (the UV range for these materials) where the compound absorbs a peak amount, preferably the greatest absorbed amount of the light energy as shown by a peak in the plot of its light energy absorption over the wavelength range. This can be observed in FIG. 1. Down conversion materials may, in some cases, have more than one maximum in absorption. For this measurement, absorption is measured using the known and commercially available UV-Vis spectrometer. As is known, in the UV spectral range of from about 280 to about 400 nm, the response of typical semiconductor materials used in prior art photovoltaic cells is significantly reduced; meaning that this range does not very effectively generate electric current. Within this general range, a down conversion material maximum in absorption is preferably at least about 325 and more preferably at least about 350 nm. Preferably, a maximum in absorption is generally less than about 400 and preferably less than about 380 nm. As shown in FIG. 1, the maximum in absorption wavelength for Lumogen™ 570 Violet is at the peak of the absorption wavelength curve, about 375 nm.

In one embodiment, such down conversion material exhibits one or more maximums in emission of electromagnetic radiation within the solar spectral range of from about 400 to about 900 nanometers. In cases where there is more than one maximum in emission preferably all such down conversion material maximums in emission fall in this range, which is possible with some down conversion materials. See, for example, FIG. 1. Within this spectral range, the spectral response of prior art photovoltaic cells is typically high, or at least better than in the UV range. Combined with a maximum absorption range described above, the down conversion would efficiently convert electromagnetic radiation from a range, in which the spectral response is poor, into a range in which the spectral response of the photovoltaic cell is higher. A “maximum in emission” of a down conversion material refers to the light wavelength out of the solar electromagnetic wave spectrum where the compound emits a peak amount, preferably the greatest percent, of the light energy as shown by a peak in the plot of its light energy emission over the wavelength range. For this measurement, light energy emission is measured by the known fluorometer, usually with a single exciting wavelength and single detection wavelength. Within this range, a maximum in emission wavelength is preferably at least about 380 nm, preferably at least about 400 nm and less than about 900 nm, more preferably than about 500 nm. As shown in FIG. 1, maximums in emission wavelength for Lumogen™ 570 Violet are at the peaks of the emission wavelength curve, about 410 nm and 435 nm. Thus, as can be seen in FIG. 1, Lumogen™ 570 Violet is an example of a down conversion material.

There are many known down conversion materials that meet the general performance standards above and are suitable for use according to the present invention. Suitable down conversion materials include one or more of the materials (solely or as mixtures) taught in the following publications:

US 2006/0169971 showing inorganic quantum dot compounds;
WO2009/157879 showing sub-micron-sized, rare earth ion doped, organic, inorganic or hybrid complexes, including organic and phosphor luminescent additives, that are capable of down conversion of light;
WO2007/042438 showing microencapsulated organic and inorganic luminescent pigments; and
WO 2008/110567 showing a range of down conversion materials and their use in photovoltaic applications;
all of which are incorporated herein by reference.

Among the suitable down conversion materials generally taught in the publications above are the following specific inorganic and organic types of down conversion materials.

Inorganic down conversion material nanoparticles include down conversion compounds selected from:

(i) nanoparticles of compounds containing photoluminescent lanthanide cations selected from the group consisting of: La, Ce, Pr, Eu, Nd, Pm, Sm, Tb, Dy, Ho, Er, Tm and Yb, and
(ii) quantum dots selected from the group of semiconductor nanocrystal compounds that can produce more than one excitons from one high energy photon of sunlight.

Included are such semiconductor nanocrystal compound down conversion materials comprising elements from:
1) Groups 2 and 16 of the Periodic Table of the Elements including binary compounds: MgO, MgS, MgSe, MgTe, CaO, CaS, CaTe, SrO, SrS, SrSe, Sae, BaO, BaS, BaSe, BaTe,
2) Groups 12 and 16 of the Periodic Table of the Elements including binary compounds: CdO, CdSe, CdTe, ZnO, ZnS, ZnSe and ZnTe, and including ternary compounds, CdSeS, CdSeTe, CdSTe, ZnSeS, ZnSeTe, ZnSTe, CdZnS, CdZnSe and CdZnTe;
3) Groups 13 and 15 of the Periodic Table of the Elements including binary compounds: including GaN, GaP, GaAs, GaSb, InP, InAs and InSb, ternary compounds, including GaNP, GaNAs, GaNSb, GaPAs, GaPSb, InNP, InNAs, InNSb, InPAs, InPSb and GaAlNP;
4) Groups 14 and 16 of the Periodic Table of the Elements including binary compounds PbO, PbO₂, PbS, PbSe, PbTe, SnS, SnSe, SnTe, SiO₂, GeO₂, SnO₂ including ternary compounds, PbSeS, PbSeTe, PbSTe, SnPbS, SnPbSe and SnPbTe;
5) Group 14 of the Periodic Table of the Elements including unary compounds Si and Ge and binary compounds SiC and SiGe.
and including down conversion composites comprising one or more of the nanoparticles or nanocrystals mentioned above having a core-shell structure, the nanoparticles or nanocrystals having a size range of from about 1 nm to about 200 nm.

Suitable organic luminescent additives having down conversion properties can be selected from the following families of organic compounds and including derivatives thereof: Rhodamine, Coumarin, Rubrene, Alq3, TPD, Gaq2Cl, Perylene dye, Naphthalene carbonic acid, and Violanthrone or iso-violanthrone.

The down conversion approach can be applied to nearly all photovoltaic modules produced today including silicon wafer based devices, as well as some thin-film photovoltaic modules. The down conversion material can, thus, be selected and formulated to boost the short-wavelength response of specific photovoltaic modules and, hence, the amount of generated current. Multiple down conversion materials that separately have relatively narrow absorption bands (such as dye mixtures) may be selected in order to cover the region of poor quantum efficiency for the relevant photovoltaic modules. Dyes are typically selected starting from the ultraviolet range and then adding dyes that exhibit shorter wavelength absorption and emission spectra. For fluorescent dyes that exhibit high luminescence quantum efficiency, a mixed broad-band absorber will still exhibit a high luminescence quantum efficiency, which exhibits the majority of its emission via the longest wavelength dye due to the energy cascading down to the lowest energy.

Depending upon the temperatures required to incorporate the down conversion materials into the light transmitting thermoplastic polymer and the temperatures employed in PV module assembly processes, it may be important to employ down conversion materials that can tolerate relatively high temperatures. For higher heat melt mixing or solution incorporation steps at or near 200° C. or a PV module lamination process at about 150° C., some fluorescent dyes such as those in the BASF Lumogen F series (perylene dyes, see description in WO 2008/110567 (equivalent to US 2010/0186801, incorporated herein by reference) are relatively stable and will not be adversely affected. Preferably the down conversion materials remain stable at (and remain capable of performing down conversion after being elevated to temperatures up to at least about 230° C., and more preferably at least about 200° C.

Preferred down conversion additives include TINOPAL OB, Lumogen™ F Yellow 083 and Lumogen F Violet 570 from BASF.

The amounts of down conversion material(s) to be employed will depend upon various factors, including the efficiency of the particular material selected and the fashion in which it is employed in a thermoplastic polymer in a photovoltaic module. In general, concentration of the down conversion material in thermoplastic polymer is in the range of from about 0.1 to about 5000 parts by weight down conversion material per million parts by weight of the thermoplastic polymer composition (ppm). Desirably, the level is at least about 10 ppm, and preferably at least about 50 ppm. In some embodiments the maximum level is less than or equal to about 1000 ppm and preferably less than or equal to about 500 ppm.

These ranges have proven to exhibit advantageous effects with regard to improvement of the quantum efficiency for most of the down conversion materials. Nevertheless, the precise optimum concentration may depend on the nature of the down conversion material and/or the host material. Also, as will be discussed further below, the structure of the photovoltaic module may determine the optimum utilization of the down conversion materials in terms of their concentration and location.

### Thermoplastic Polymer Resin Stabilization Materials

In addition to the down conversion materials discussed above, selected light stabilizer compounds are required to provide optimized combinations of thermoplastic polymer stabilization and photovoltaic performance according to the present invention. Depending somewhat on the thermoplastic resin being stabilized, the stabilizer compound(s) can be selected to provide needed protection of the polymer physical properties against UV-induced degradation and still permit the down conversion of the higher energy wavelengths of the electromagnetic radiation to provide improved cell performance.

Preferably employed is one or more light stabilizer additive that, when used in the resins and films in concentrations that are sufficient to provide necessary levels of stabilization, transmits at least about 40 percent of the ultraviolet (UV) electromagnetic radiation having a wavelength in the UV range of from about 280 nm to about 380 nm. This means that when the light stabilizer compound is tested for its light transmittance across the wavelengths in this range, it will have at least 50% transmittance measured over the full range. It can be determined that a light stabilizer additive transmits at least about 40 percent of the ultraviolet (UV) electromagnetic radiation having a wavelength in the UV range of from about 280 nm to about 380 nm is measured by observing the plot or chart of radiation transmission at the various wavelengths that is obtained using a UV-Vis spectrometer and determining that, over that wavelength range, the light transmittance is at least about 50% at every wavelength.

Also desirably, the stabilizer compound molecular weight is at least about 500 AU, or more preferably at least about 1000 AU, which relatively high molecular weights will slow down the migration of additive in the field application.

Particularly useful in this regard is the use of at least one hindered amine light stabilizer (“HALS”) that provide stabilization effects without blocking or absorbing the transmittance of the targeted wavelength radiation. Without in any way restricting the scope of the invention, it is theorized that these additives scavenge radicals which are generated in the thermoplastic polymers by the UV radiation and would otherwise cause the polymer degradation process. This is possibly explained by the formation of nitroxyl radicals through a process known as the Denisov Cycle where a nitroxyl radical (R—O.) combines with free radical in polymers. In general, such additives do not significantly absorb the electromagnetic radiation of wavelengths in UVA (320 nm and 380 nm) or UVA and UVB (280 nm to 320 nm) ranges that can be down converted utilizing one or more of the down conversion materials noted above. Without in any way being bound by the theory, as another desirable attribute of such stabilizer compound(s) it is theorized that there is a polar-polar interaction and/or hydrogen bonding of such light stabilizer with down conversion materials. It is theorized that, if present, this will slow down the migration of both down conversion materials and UV additives within the polymer matrix, improve the UV stability of the down conversion material and/or improve the dispersion of both additives in certain thermoplastic polymers, particularly polyolefins.

In addition to HALS-types, there are also other suitable types of non-HALS light stabilizers such as excited state quenchers, hydroperoxide decomposers, and radical scavengers. Examples of these would include Cyasorb UV-1084 ([2,2-Thiobis(4-tert-octylpheonlato)]-n-butylamine, Nickel), a hydroperoxide decomposer, and Cyasorb UV-2908 (3,5-di-tert-butyl-4-hydroxybenzoic acid, hexadecyl ester), a radical scavenger. Some suitable light stabilizers are shown in the following Table:

TABLE 1
Light Stabilizers

| Name | Supplier | MW | Type |
|---|---|---|---|
| Cyasorb 3346 | Cytech | 1600 | HALS |
| Cyasorb 3529 | Cytech | 1700 | HALS |
| Cyasorb 2908 | Cytech | 475 | non-HALS |
| Cyaborb 3853 | Cytech | 400-500 | HALS |
| Chimassorb 944 LD | Ciba | 2000-3100 | HALS |
| Tinuvin 622 | Ciba | 3100-4000 | HALS |
| Tinuvin 123 | Ciba | 737-1630 | HALS |
| Univul 4050 | BASF | 450 | HALS |
| Univul 5050 | BASF | 3500 | HALS |
| Hostavin N30 | Clariant | >1000 | HALS |
| Chimassorb UV 119 | Ciba | 2285 | HALS |

The levels of these additives needed to provide the light stabilization effect varies somewhat based on the specific stabilizer but is generally in the range of from about 0.01 to about 5 weight percent based on the weight of polymer being stabilized. In particular, the needed amount of light stabilizer is preferably from about 0.02 to about 0.5 weight percent based upon total thermoplastic polymer composition weight, and more preferably from about 0.05 to about 0.15 weight percent.

The selection of any other stabilizing additives, if any, should coordinate with the intended UV down conversion performance. In general, UV absorbers which detrimentally affect the down conversion should be avoided.

Phosphorus-containing stabilizer compounds can also be used, including for example phosphonites (PEPQ) and phosphites (Weston 399, TNPP, P-168 and Doverphos 9228). The amount of processing stabilizer is typically from about 0.02 to 0.5%, and preferably from about 0.05 to 0.15%.

Thus, such other additives include but are not limited to:
antioxidants (e.g., hindered phenolics such as Irganox® 1010) in amounts of from about 0.02 to about 0.5 weight percent based upon total thermoplastic polymer composition weight, and more preferably from about 0.05 to about 0.15 weight percent;
cling additives (e.g., polyisobutylene),
anti-blocks,
anti-slips,
pigments and fillers (as permitted based upon transmittance/transparency requirements in the application).

In-process additives, e.g. calcium stearate, mineral oil, water, etc., may also be used. Other potential additives are used in the manner and amount as is commonly known in the art.

### Thermoplastic Polymer Components

As discussed in more detail below, high light transmittance thermoplastic polymers, and thermoplastic polyolefin copolymers in particular, may be employed in one or more of the different photovoltaic module elements or components. The following terms are used in referring to the polymer materials and the layers, films, elements, and/or components in which they are employed.

“Composition” and like terms mean a mixture of two or more materials. Included in compositions are pre-reaction, reaction and post-reaction mixtures, the latter of which will include reaction products and by-products as well as unreacted components of the reaction mixture and decomposition products, if any, formed from the one or more components of the pre-reaction or reaction mixture.

“Blend”, “polymer blend” and like terms mean a composition of two or more polymers. Such a blend may or may not be miscible. Such a blend may or may not be phase separated. Such a blend may or may not contain one or more domain configurations, as determined from transmission electron spectroscopy, light scattering, x-ray scattering, and any other method known in the art. Blends are not laminates, but one or more layers of a laminate may contain a blend.

A “polymer” or stated type of polymer means a polymeric material or resin prepared by polymerizing monomers, whether all monomers are the same type as stated or including some monomeric units of a different type. The generic term polymer thus embraces the term homopolymer, usually employed to refer to polymers prepared from only one type of monomer, and the term interpolymer or copolymer as defined below. It also embraces all forms of interpolymers, e.g., random, block, etc. The terms “ethylene/α-olefin polymer”, “propylene/α-olefin polymer” and “silane copolymer” are indicative of interpolymers as described below.

“Interpolymer” or “copolymer” may be used interchangeably and refer to a polymer prepared by the polymerization of at least two different monomers. This generic term includes copolymers prepared from two or more different monomers, e.g., terpolymers, tetrapolymers, etc.

The terms “high light transmittance” referring to a material, film or layer are referring to solar radiation and mean light transmission rates in excess of at least about 85, preferably at least about 90, preferably in excess of 95 and even more preferably in excess of 97, percent as measured by UV-vis spectroscopy (measuring absorbance in the wavelength range of about 280-1200 nanometers. An alternative measure of transmittance is the internal haze method of ASTM D-1003-00. Transmittance can be a function of the thickness of the material, film or layer that is tested and, as used herein, refers to “transmittance” in a thickness as typically employed in the films or layers of the typical PV modules, generally in the range of from about 50 to about 1000 micrometers (“μm”), from about 15 to about 18 mil.

In general, the down conversion materials discussed above, in combination with the selected hindered amine light stabilizers can be employed in a broad range of light transmitting thermoplastic polymer resins (also often generally referred to as polymers, resins, plastics and/or plastic resins). In particular, based upon their desirable combinations of optical, electrical and physical properties and cost-effectiveness, a broad range of light transmitting thermoplastic polyolefin copolymers can be employed in the layers in the laminate film structures provided they can be formed into thin film or sheet layers and provide the desired physical properties. Alternative or preferred embodiments of the invention may employ one or more of the specific types of thermoplastic polyolefin copolymers and/or specific thermoplastic polyolefin copolymers in specific layers, as will be discussed further below. Preferably, the light transmitting thermoplastic polymers exhibit a transmission above 50%, preferably above 85%, more preferably above 85% over the full range of the visible spectrum.

The polyolefin copolymers useful in the practice of this invention are preferably polyolefin interpolymers or copolymers, more preferably ethylene/alpha-olefin interpolymers. These interpolymers have an α-olefin content needed to provide the prescribed density, generally of at least about 15, preferably at least about 20 and even more preferably at least about 25, weight percent (wt %) based on the weight of the interpolymer. These interpolymers typically have an α-olefin content of less than about 50, preferably less than about 45, more preferably less than about 40 and even more preferably less than about 35, wt % based on the weight of the interpolymer. The presence of an α-olefin and content is measured by ¹³C nuclear magnetic resonance (NMR) spectroscopy using the procedure described in Randall (Rev. Macromol. Chem. Phys., C29 (2&3)). Generally, the greater the α-olefin contents of the interpolymer, the lower the density and the more amorphous the interpolymer.

The α-olefin is preferably a C₃₋₂₀ linear, branched or cyclic α-olefin. Examples of C₃₋₂₀α-olefins include propene, 1-butene, 4-methyl-1-pentene, 1-hexene, 1-octene, 1-decene, 1-dodecene, 1-tetradecene, 1-hexadecene, and 1-octadecene. The α-olefins can also contain a cyclic structure such as cyclohexane or cyclopentane, resulting in an α-olefin such as 3-cyclohexyl-1-propene (allyl cyclohexane) and vinyl cyclohexane. Although not α-olefins in the classical sense of the term, for purposes of this invention certain cyclic olefins, such as norbornene and related olefins, are α-olefins and can be used in place of some or all of the α-olefins described above. Similarly, styrene and its related olefins (for example, α-methylstyrene, etc.) are α-olefins for purposes of this invention. However, acrylic and methacrylic acid and their respective ionomers, and acrylates and methacrylates, and other similarly polar or polarizing unsaturated comonomers are not α-olefins for purposes of this invention. Illustrative polyolefin copolymers include ethylene/propylene, ethylene/butene, ethylene/1-hexene, ethylene/1-octene, ethylene/styrene, and the like. Ethylene/acrylic acid (EAA), ethylene/methacrylic acid (EMA), ethylene/acrylate or methacrylate, ethylene/vinyl acetate and the like copolymers similarly having polar or polarizing unsaturated comonomers are not thermoplastic polyolefin copolymers or interpolymers for purposes of the scope of this invention. Illustrative terpolymers that can be thermoplastic polyolefin copolymers or interpolymers for purposes of the scope of this invention include ethylene/propylene/1-octene, ethylene/propylene/butene, ethylene/butene/1-octene, and ethylene/butene/styrene. The copolymers can be random or block-type.

In general, relatively low density thermoplastic polyolefin copolymers are useful in the practice of this invention. In general, these are the “base” polymers that are preferably grafted or functionalized to contain alkoxysilane or, in the case of the alkoxysilane-containing copolymers, would be polymerized containing the copolymerized alkoxysilane. Typically they would have a density of less than about 0.930 grams per cubic centimeter (g/cm³), preferably less than about 0.920, preferably less than about 0.910, preferably less than about 0.905, more preferably less than about 0.890, more preferably less than about 0.880 and more preferably less than about 0.875, grams per cubic centimeter (g/cm³). There is not, in most cases, a strict lower limit for the density of the polyolefin copolymers, but, for purposes of typical commercial processes of production, pelletizing, handling and/or processing of the resin, they will typically have a density greater than about 0.850, preferably greater than about 0.855 and more preferably greater than about 0.860, g/cm³. Density is measured by the procedure of ASTM D-792. These relatively low density polyolefin copolymers are generally characterized as semi-crystalline, flexible, resistant to water vapor transmission and having good optical properties, e.g., high transmission of visible and UV-light and low haze.

In general, the thermoplastic polyolefin copolymers useful in the practice of this invention desirably exhibit a melting point of less than about 125° C. This generally permits lamination using known and commercially available glass lamination processes and equipment. In cases of specific types of thermoplastic polyolefin copolymers useful in the practice of this invention, as discussed below, there may be preferred melting point ranges. The melting points of the thermoplastic polyolefin copolymers can be measured, as known to those skilled in the art, by differential scanning calorimetry (“DSC”), which can also be used to determine the glass transition temperatures (“Tg”) as mentioned below.

Further features of these copolymers that are also desirable include optionally, one or more of the following properties:
a 2% secant modulus of less than about 150 megaPascal (MPa) has measured by ASTM D-790, and
a glass transition temperature (Tg) of less than about −35° C. as measured by DSC.

The polyolefin copolymers useful in the practice of this invention typically have a melt index of greater than or equal to about 0.10, preferably greater than or equal to about 1 gram per 10 minutes (g/10 min) and less than or equal to about 75 and preferably of less than or equal to about 10 g/10 min. Melt index is measured by the procedure of ASTM D-1238 (190° C./2.16 kg).

More specific examples of the polyolefin copolymers useful in this invention prior to or excluding the alkoxysilane incorporation include very low density polyethylene (VLDPE) (e.g., FLEXOMER® ethylene/1-hexene polyethylene made by The Dow Chemical Company), homogeneously branched, linear ethylene/alpha-olefin copolymers (e.g. TAFMER® by Mitsui Petrochemicals Company Limited and EXACT® by Exxon Chemical Company), homogeneously branched, substantially linear ethylene/alpha-olefin polymers (e.g., AFFINITY® and ENGAGE® polyethylene available from The Dow Chemical Company), and olefin block copolymers (OBC's) such as those described in U.S. Pat. No. 7,355,089 (e.g., INFUSE® available from The Dow Chemical Company). Specific preferred types of polyolefin copolymers include olefin block-type copolymers (OBC) and homogeneously branched, substantially linear ethylene copolymers (SLEP).

Regarding the preferred homogeneously branched substantially linear ethylene copolymers (SLEP's), these are examples of “random polyolefin copolymers” and the description of these types of polymers and their use in PV encapsulation films is discussed in 2008/036708 and they are more fully described in U.S. Pat. Nos. 5,272,236, 5,278,272 and 5,986,028, all of which are incorporated herein by reference. As is known, the SLEP-types of polyolefin copolymers are preferably made with a single site catalyst such as a metallocene catalyst or constrained geometry catalyst. These polyolefin copolymer typically have a melting point of less than about 95° C., preferably less than about 90° C., more preferably less than about 85° C., even more preferably less than about 80° C. and still more preferably less than about 75° C.

Similarly preferred are the olefin block copolymer (OBC) types of polyolefin copolymers, which are examples of “block-type polyolefin copolymers” and are typically made with chain shuttling-types of catalysts. The description of these types of polymers in their use in PV encapsulation films is discussed in 2008/036707, incorporated herein by reference. These block-types of polyolefin copolymers typically have a melting point of less than about 125° C. and preferably from about 95° C. to about 125° C.

For other types of polyolefin copolymers made with multi-site catalysts, e.g., Ziegler-Natta and Phillips catalysts, the melting point is typically from about 115 to 135° C. The melting point is measured by differential scanning calorimetry (DSC) as described, for example, in U.S. Pat. No. 5,783,638. Polyolefin copolymers with a lower melting point often exhibit desirable flexibility and thermoplasticity properties useful in the fabrication of the modules of this invention. Similarly suitable is an ethylene-based block-type polymer as described in U.S. Pat. No. 5,798,420 and having an A block and a B block, and if a diene is present in the A block, a nodular polymer formed by coupling two or more block polymers.

Blends of any of the above thermoplastic polyolefin copolymer resins can also be used in this invention and, in particular, the thermoplastic polyolefin copolymers can be blended or diluted with one or more other polymers to the extent that the polymers are (i) miscible with one another, (ii) the other polymers have little, if any, impact on the desirable properties of the polyolefin copolymer, e.g., optics and low modulus, and (iii) the thermoplastic polyolefin copolymers of this invention constitute at least about 70, preferably at least about 75 and more preferably at least about 80 weight percent of the blend. Preferably the blend itself also possesses the density, melt index and melting point properties noted above.

As also known, to provide some light transmitting thermoplastic polymers, and thermoplastic polyolefin copolymers in particular, with desired or needed improvements in adhesion, heat resistance and toughness-related physical properties, alkoxysilane groups can be incorporated into the thermoplastic polymer resin using known monomeric reactants in a polymerization process, known grafting techniques, or other functionalization techniques. Any types and amounts of alkoxysilane group-containing compound or monomer that will effectively improve the adhesion, heat resistance and/or toughness-related physical performance of the thermoplastic polyolefin resin and can be grafted/incorporated therein and subsequently crosslinked, can be used in the practice of this invention. Use of catalysts and other techniques that facilitate the incorporation, use and performance of the alkoxysilane groups are also known and can be employed as possible and appropriate for alkoxysilane-containing light transmitting thermoplastic polymers utilized according to the present invention.

Depending somewhat on the specific down conversion material being employed in the thermoplastic polymer, the down conversion materials and light stabilizer can be incorporated into the thermoplastic polymer together or in sequence in any of the generally well known techniques for incorporating thermoplastic resin additives. The polymeric material may be mixed with a masterbatch containing the down conversion material, such as particles of a dye-containing polymer such as a dye-doped PMMA, or down conversion materials such as semiconductor quantum dots (nanocrystals) may be mixed in directly. Such mixing techniques and devices include but are not limited to known types of melt mixing with single or twin screw extruders, kneaders, mixers, and the like, including those referred to as Banbury and Haake. Some down conversion materials, such as some organic dyes, may be dissolved into the light transmitting thermoplastic polymer.

As mentioned above, according to the present invention the stabilized thermoplastic polymer compositions comprising the down conversion materials can advantageously be employed in a number of different types of structures and applications including layers or films that are employed in photovoltaic modules. The following terms refer to the components and structure for such films, layers, structures and applications:

“Layer” or “film” as referring to the use of the thermoplastic polymers comprising down conversion materials, means a relatively thin, single sheet, thickness, coating or stratum. “Film” materials are typically produced by known processes and recovered for subsequent use (including as a “layer”). In the case of a “layer”, a film or a relatively thin coating or stratum is continuously or discontinuously provided in or on a laminate structure either internally or externally, optionally along with one or more additional layer, by known processes such as coextrusion or one of the many known coating technologies.

“Multi-layer” means at least two layers.

“Facial surface” and like terms refer to the two major surfaces of the films or layers that are either an exterior or outer-facing surface (of a film) or are in contact with the opposite and adjacent surfaces of the adjoining layers in a laminate structure. Facial surfaces are in distinction to edge surfaces. A rectangular film or layer comprises two facial surfaces and four edge surfaces. A circular film or layer would comprise two facial surfaces and one continuous edge surface.

Layers that are in “facial contact” (and like terms), means that there is contact throughout substantially the entire facial surfaces of two different adjacent layers.

Layers that are in “adhering contact” (and like terms), means that facial surfaces two different layers are in touching and binding contact to one another such that one layer cannot be removed for the other layer without damage to the in-contact facial surfaces of one or both layers.

Depending somewhat upon the specific structure and process for utilizing the thermoplastic polymers comprising down conversion materials and light stabilizer, the thermoplastic polymer composition is typically prepared as a film, or at least one layer of a film, which films and film structures can be prepared by any of a large number of known film production processes including but not limited to extrusion or co-extrusion methods such as blown-film, modified blown-film, calendaring and casting. The components can be incorporated, for example, in the same or different layers of multilayer films according to the known techniques of providing multiple layers and providing nearly any number of layers up to and including the structures known in the art containing large numbers of layers and often referred to as “microlayer” structures. There are many known techniques which can be employed for multilayer films (up to and including microlayer films), including for example in U.S. Pat. No. 5,094,788; U.S. Pat. No. 5,094,793; WO/2010/096608; WO 2008/008875; U.S. Pat. No. 3,565,985; U.S. Pat. No. 3,557,265; U.S. Pat. No. 3,884,606; U.S. Pat. No. 4,842,791 and U.S. Pat. No. 6,685,872 all of which are hereby incorporated by reference herein.

“Photovoltaic cells” (“PV cells”) contain one or more photovoltaic effect materials of any of several inorganic or organic types which are known in the art and from prior art photovoltaic module teachings. For example, commonly used photovoltaic effect materials include one or more of the known photovoltaic effect materials including but not limited to crystalline silicon, polycrystalline silicon, amorphous silicon, copper indium gallium (di)selenide (CIGS), copper indium selenide (CIS), cadmium telluride, gallium arsenide, dye-sensitized materials, and organic solar cell materials.

The PV cells have at least one light-reactive surface that converts the incident light into electric current. Photovoltaic cells are well known to practitioners in this field and are generally packaged into photovoltaic modules that protect the cell(s) and permit their usage in their various application environments, typically in outdoor applications. As used herein, PV cells may be flexible or rigid in nature and include the photovoltaic effect materials and any protective coating surface materials that are applied in their production as well as appropriate wiring and electronic driving circuitry (not shown).

“Photovoltaic modules” (“PV Modules”) contain one or more PV cells in protective enclosures or packaging that protect the cell units and permit their usage in their various application environments, typically in outdoor applications. Encapsulation films are typically used in modules disposed over and covering one or both surfaces of the PV cells.

As generally known in the art, a photovoltaic module for the conversion of incident electromagnetic radiation into electric energy, and to which the thermoplastic polymer compositions according to this invention are particularly suited, comprises: (i) a light transmitting exterior surface cover sheet; (ii) at least one thermoplastic resin encapsulation film or layer providing protection to a photovoltaic cell from environmental effects, (iii) an optional protective exterior surface back sheet and (iv) least one photovoltaic cell adapted to convert electromagnetic radiation that has passed through the cover sheet and encapsulation film into electric energy. According to one embodiment of the present invention, layer or component (ii) is a stabilized thermoplastic resin sheet material that comprises at least one down conversion material adapted for at least partially absorbing the incident radiation and for re-emitting this radiation at a longer wavelength.

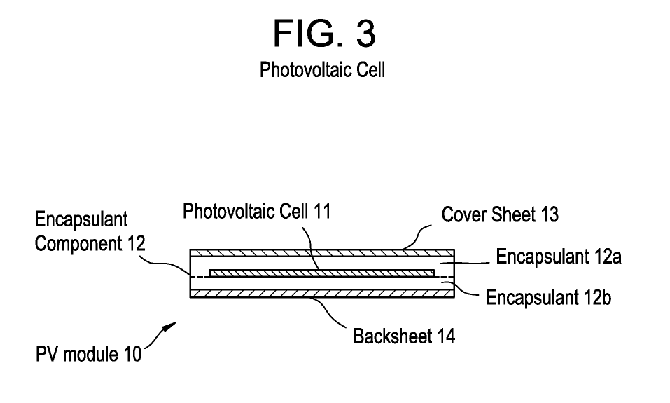

As can be seen in FIG. 3, a PV module 10 comprises at least one photovoltaic cell 11 (in this case having a light-reactive or effective surface directed or facing upward in the direction of the top of the page) surrounded or encapsulated by light transmitting protective encapsulating component 12 (shown here as a combination of two “sandwiching” sub-layers 12a and 12b). The light transmitting cover sheet 13 has an interior surface in adhering contact with a front facial surface of the encapsulating film layer 12a, which layer 12a is, in turn, disposed over and in adhering contact with PV cell 11. Back sheet 14 acts as a substrate and supports a rear surface of the PV cell 11 and optional encapsulating film layer 12b, which, in this case is disposed on a rear surface of PV cell 11. Back sheet layer 14 (and even encapsulating sub-layer 12b) need not be light transmitting if the surface of the PV cell to which it is opposed is not effective, i.e., reactive to sunlight. In this embodiment which is typical of rigid PV module, encapsulating film 12 encapsulates PV cell 11 by a “sandwich” of two layers. The thicknesses of these layers, both in an absolute context and relative to one another, are not critical to this invention and as such, can vary widely depending upon the overall design and purpose of the module. Typical thicknesses for protective layers 12a and 12b are in the range of about 0.125 to about 2 millimeters (mm), and for the cover sheet and back sheet layers in the range of about 0.125 to about 1.25 mm. The thickness of the electronic device can also vary widely.

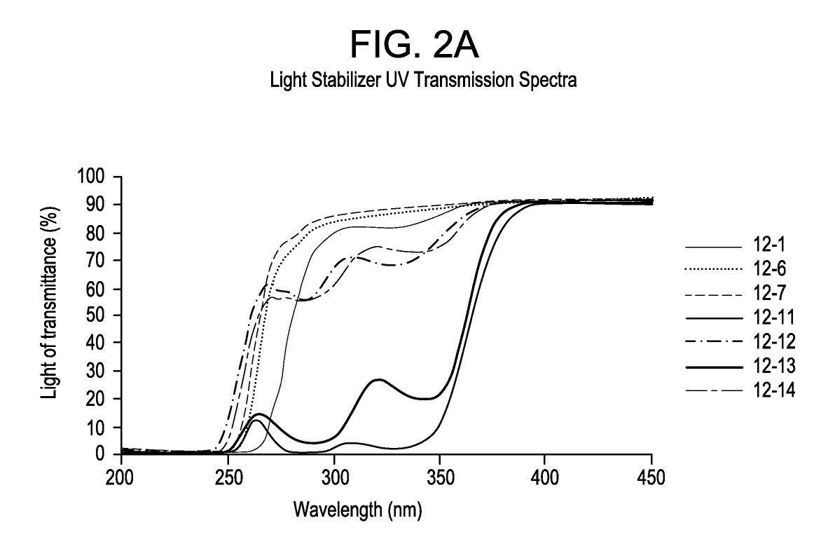

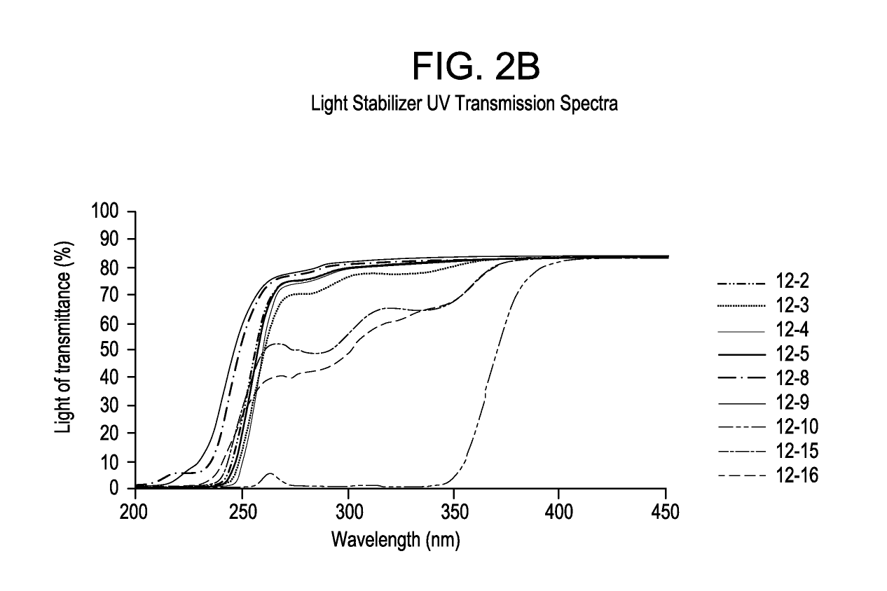

In the case of a flexible PV module, the structure is similar but, as the description “flexible” implies, it would comprise a flexible thin film photovoltaic cell 11 with a single light-reactive surface (directed upward in the direction of the top of the page in FIG. 2). Top layer 13 covers and is adhered to a front facial surface of the light transmitting encapsulating film layer 12a, which layer 12a is disposed over and in adhering facial contact with thin film PV cell 11. Flexible back sheet 14 is a second protective layer that supports the bottom surface of thin film PV 11 (and can be the same as or similar to the encapsulating layer and/or the top layer) but need not be light transmitting if the surface of the thin film cell which it is supporting is not reactive to sunlight. In one flexible PV module embodiment, the PV cell 11 is applied or adhered directly to the backsheet 14 (there is no protective layer 12b) and the thin film photovoltaic cell 11 is effectively “encapsulated” by protective layer 12a and backsheet layer 14. The overall thickness of a typical rigid or flexible PV cell module will typically be in the range of about 5 to about 50 mm.

### Light Transmitting Encapsulation Component or Layer

The light transmitting thermoplastic polymers comprising the down conversion/light stabilizer formulations according to present invention can most advantageously be employed in the light transmitting encapsulation layer or layers of PV modules. These layers are sometimes referred to in various types of PV module structures as “encapsulation” films or layers or “protective” films or layers or “adhesive” films or layers. Typically, these layers function to encapsulate and protect the interior photovoltaic cell from moisture and other types of physical damage and adhere it to other layers, such as a glass or other top sheet material and/or a back sheet layer. Optical clarity, good physical and moisture resistance properties, moldability and low cost are among the desirable qualities for such films. The polymer compositions and particularly the films of the present invention can be used in the same manner and amounts as the light transmitting layers used in the known PV module laminate structures, e.g., such as those taught in U.S. Pat. No. 6,586,271, US Patent Application Publication US2001/0045229 A1, WO 99/05206 and WO 99/04971. These materials can be used as the light transmitting “skin” for the PV cell, i.e., applied to any faces or surfaces of the device that are light-reactive. Optionally, very similar materials and layers, not comprising the down conversion material can be employed as an encapsulation layer for any faces or surfaces of the device that are not light-reactive.

As described further below, for this component, the thermoplastic polymers comprising the down conversion/light stabilizer formulations according to present invention can be applied to the PV cell device as a separate coating or layer or, preferably, a film structure comprising at least one layer of the thermoplastic polymers comprising the down conversion/light stabilizer formulations according to present invention can first be prepared and then applied to light-reactive facial surfaces of the device either sequentially or simultaneously.

### Light Transmitting Cover Sheet

Light transmitting cover sheet layers, sometimes referred to in various types of PV module structures as “cover”, “protective” and/or “top sheet” layers, can be one or more of the known rigid or flexible sheet materials. Alternatively to glass or in addition to glass, other known materials can be employed for one or more of the layers with which the lamination films according to the present invention are employed. Such materials include, for example, materials such as polycarbonate, acrylic polymers, a polyacrylate, a cyclic polyolefin such as ethylene norbornene, metallocene-catalyzed polystyrene, polyethylene terephthalate, polyethylene naphthalate, fluoropolymers such as PTFE (ethylene-tetrafluoroethlene), PVF (polyvinyl fluoride), FEP (fluoroethylene-propylene), ECTFE (ethylene-chlorotrifluoroethylene), PVDF (polyvinylidene fluoride), and many other types of plastic or polymeric materials, including laminates, mixtures or alloys of two or more of these materials. The location of particular layers and need for light transmission and/or other specific physical properties would determine the specific material selections. As needed and possible based upon their composition, the down conversion/light stabilizer formulations discussed above can be employed in the transparent cover sheets. However, the inherent stability of some of these may not require light stabilization according to the present invention.

When used in certain embodiments of the present invention, the “glass” used as a light transmitting cover sheet refers to a hard, brittle, light transmitting solid, such as that used for windows, many bottles, or eyewear, including, but not limited to, soda-lime glass, borosilicate glass, sugar glass, isinglass (Muscovy-glass), or aluminum oxynitride. In the technical sense, glass is an inorganic product of fusion which has been cooled to a rigid condition without crystallizing. Many glasses contain silica as their main component and glass former.

Pure silicon dioxide (SiO₂) glass (the same chemical compound as quartz, or, in its polycrystalline form, sand) does not absorb UV light and is used for applications that require transparency in this region. Large natural single crystals of quartz are pure silicon dioxide, and upon crushing are used for high quality specialty glasses. Synthetic amorphous silica, an almost 100% pure form of quartz, is the raw material for the most expensive specialty glasses.

The glass layer of the laminated structure is typically one of, without limitation, window glass, plate glass, silicate glass, sheet glass, float glass, colored glass, specialty glass which may, for example, include ingredients to control solar heating, glass coated with sputtered metals such as silver, glass coated with antimony tin oxide and/or indium tin oxide, E-glass, and Solexia™ glass (available from PPG Industries of Pittsburgh, Pa.).

### Back Sheet or Rear Layers

Additionally, photovoltaic modules may comprise an additional rear layer, also referred to some cases as “back sheet” or the like, wherein the rear layer is adapted for providing additional protection of the photovoltaic module against moisture and is light transmitting or not, depending upon the capability of the PV cell that is being employed. Depending upon the needs of the specific structures, the rear layer may have laminated to it one or more of: the encapsulation element, the back side of the PV cell and/or to the light transmitting cover sheet. Depending the desired combinations of properties, the rear layer can be selected from a range of materials including the top sheet materials and, if permitted non-light-transmitting materials such as metal layers, with the function of providing the needed and cost effective balance of physical properties, moisture barrier and weight. For example, fluorinated polymeric materials, such as polyvinyl fluoride (e.g., “Tedlar” brand materials) have proven to be suitable materials to be used in or as the rear layer, providing light weight, good moisture protection and lower cost as compared to a rear glass sheet. As appropriate based on the specific structure type and module design, for example, where light is reflected from the backsheet, light transmitting rear layers could optionally employ the down conversion/light stabilizer formulations according to the present invention.

### Laminated PV Module Structures

The methods of making PV modules known in the art can readily be adapted to use the light transmitting thermoplastic polymers comprising the down conversion/light stabilizer formulations according to present invention, and most advantageously employ them in the light transmitting encapsulation layer or layers of PV modules. For example, the light transmitting thermoplastic polymers comprising the down conversion/light stabilizer formulations according to present invention can be used in the PV modules and methods of making PV modules such as those taught in U.S. Pat. No. 6,586,271, US Patent Application Publication US2001/0045229 A1, WO 99/05206 and WO 99/04971, and preferably in the light transmitting encapsulation layer or layers of PV modules.

In general, in the lamination process to construct a laminated PV module, at least the following layers are brought into facial contact:
a light-receiving top sheet layer (e.g., a glass layer) having an “exterior” light-receiving facial surface and an “interior” facial surface;
a light transmitting thermoplastic polymer film having at least one layer of light transmitting thermoplastic polymers comprising the down conversion/light stabilizer formulations according to present invention, having one facial surface directed toward the glass and one directed toward the light-reactive surface of the PV cell and encapsulating the cell surface;
a PV cell;
if needed, a second encapsulating film layer (optionally according to the present invention); and
a back layer comprising glass or other back layer substrate.

With the layers or layer sub-assemblies assembled in desired locations the assembly process typically requires a lamination step with heating and compressing at conditions sufficient to create the needed adhesion between the layers and, if needed in some layers or materials, initiation of their crosslinking. If desired, the layers may be placed into a vacuum laminator for 10 to 20 minutes at lamination temperatures in order to achieve layer-to-layer adhesion and, if needed, crosslinking of the polymeric material of the encapsulation element. In general, at the lower end, the lamination temperatures need to be at least about 130° C., preferably at least about 140° C. and, at the upper end, less than or equal to about 170° C., preferably less than or equal to about 160° C.

As used in this description, numerical ranges include all values from and including the lower and the upper values, in increments of one unit, provided that there is a separation of at least two units between any lower value and any higher value. As an example, if a parameter is from 100 to 1,000, it is intended that all individual values, such as 100, 101, 102, etc., and sub ranges, such as 100 to 144, 155 to 170, 197 to 200, etc., are expressly enumerated. For ranges containing values which are less than one or containing fractional numbers greater than one (e.g., 1.1, 1.5, etc.), one unit is considered to be 0.0001, 0.001, 0.01 or 0.1, as appropriate. For ranges containing single digit numbers less than ten (e.g., 1 to 5), one unit is typically considered to be 0.1. These are only examples of what is specifically intended, and all possible combinations of numerical values between the lowest value and the highest value enumerated, are to be considered to be expressly stated in this disclosure.

The term “comprising” and its derivatives are not intended to exclude the presence of any additional component, step or procedure, whether or not the same is specifically disclosed. In order to avoid any doubt, any process or composition claimed through use of the term “comprising” may include any additional steps, equipment, additive, adjuvant, or compound whether polymeric or otherwise, unless stated to the contrary. In contrast, the term, “consisting essentially of” excludes from the scope of any succeeding recitation any other component, step or procedure, excepting those that are not essential to operability. The term “consisting of” excludes any component, step or procedure not specifically delineated or listed. The term “or”, unless stated otherwise, refers to the listed members individually as well as in any combination.

The following examples further illustrate the invention. Unless otherwise indicated, all parts and percentages are by weight.

### EXPERIMENTS

Initially light stabilizer additives and formulations are evaluated for their “transparency” to 300 nanometer (nm) light in order to determine their suitability for use with down conversion materials. Films were prepared as described below and evaluated to determine whether encapsulant films comprising the light stabilizer materials would sufficiently transmit the shorter wavelength, higher energy light that could be employed in “down conversion” layers in photovoltaic devices. The films were prepared from base resin formulations comprising the light stabilizer components identified below in Table 2 in the amounts indicated in Table 3 but without any down conversion material. As shown in Table 3 and FIG. 2, below, there were a number of the stabilizers that will transmit radiation sufficient and suitable for down conversion.

### Experimental Film Samples 1-20

### Base Resin:

The base resin was ENGAGE™ 8200 brand thermoplastic polyolefin copolymer. It was grafted with a typical alkoxysilane to simulate a typical PV module encapsulation layer film and contained about 1.2 weight percent grafted trialkoxysilane groups as determined by neutron activation analysis.

ENGAGE™ 8200 Brand Thermoplastic Polyolefin Copolymer

Density—0.870 grams per cubic centimeter (g/cc) as measured by ASTM D792.

Melt Index—5 g/10 min as measured by ASTM D-1238 (190° C./2.16 kg).

Melting point—59° C. as measured by differential scanning calorimetry.

2% secant modulus—1570 psi (10.8 MPa) as measured by ASTM D-790,

α-olefin—1-octene

Tg of −63.4° F. (−53° C.) as measured by differential scanning calorimetry.

### Light Stabilization Additives:

The following light stabilization additives shown in Table 2 below were added to resin formulations in the amounts shown in Table 3. In Table 3, the light stabilizer identification numbers refer to the commercial designations of compounds as shown in Table 2, below. The amounts of the additives that were incorporated are shown in parenthesis, given as parts additive per million parts plastic base resin (ppm), with 1000 parts per million being the equivalent of 0.1 weight percent.

TABLE 2
Stabilizers and additives

| Comm- | | | Used in |
|---|---|---|---|
| ercial | | | Expt'l |
| Des- | | | Film(s) |
| ignation | Type | Structure | No. |
| Chim- assorb 119 | HALS | 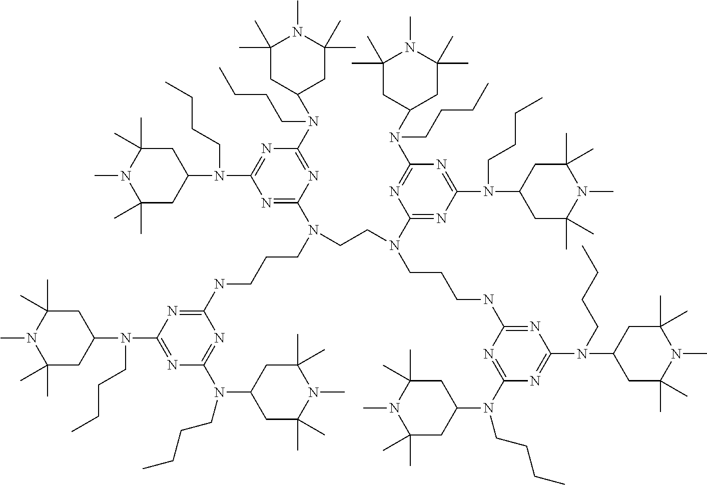 | 17 |
| Tin- uvin 622 | HALS | 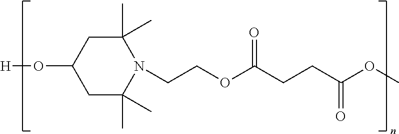 | 2, 3, 4, 5, 19 |
| Tin- uvin 123 | | 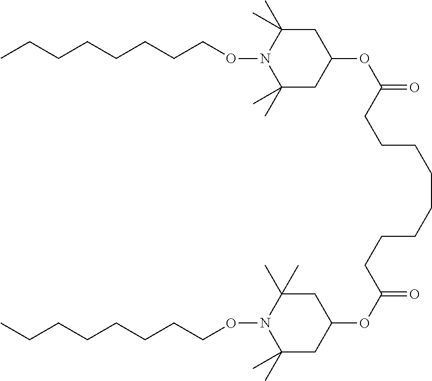 [SMILES: CCCCCCCCON1C(C)(C)CC(OC(=O)CCCCCCCCC(=O)OC2CC(C)(C)N(OCCCCCCCC)C(C)(C)C2)CC1(C)C] | 7 |
| Chim- assorb 944 LD | HALS | 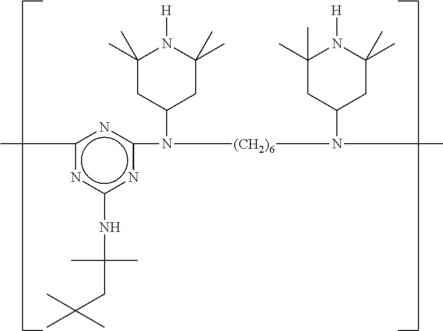 | 2, 3, 4, 5, 18 |
| Cya- sorb 3346 | HALS | UV-3346 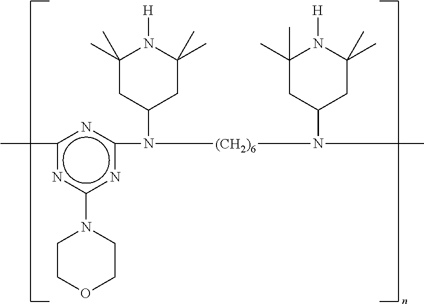 | 6, 13 |
| Cya- sorb 3529 | HALS | 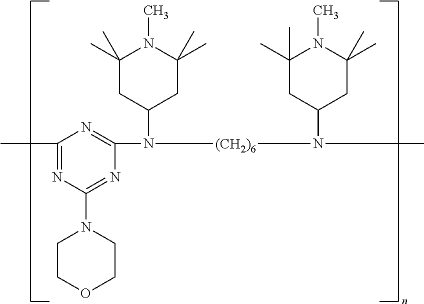 | 6, 8, 9, 10, 11, 12, 13 |
| Cya- sorb 3853 | HALS | 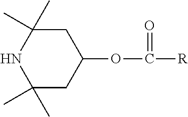 Where R is: C₁₁-C₂₀ Predominantly, C₁₆-C₁₉ | 13 |
| Host- avin N30 | HALS | 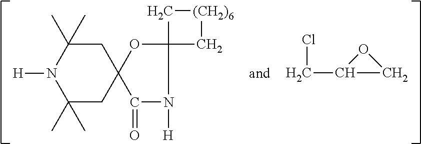 Hostavin N 30 | 15 |
| Univul 4050 | HALS | 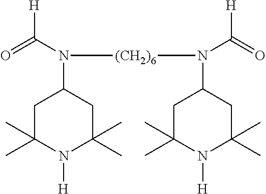 | 14, 16 |
| Univul 5050 | HALS | 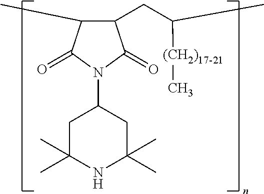 | 16 |

Other Light Stabilizer

| | | | |
|---|---|---|---|
| Cya- sorb 2908 | Non- HALS | 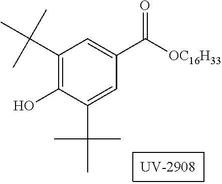 | 12 |

UV absorbers

| | | |
|---|---|---|
| UV 531 | 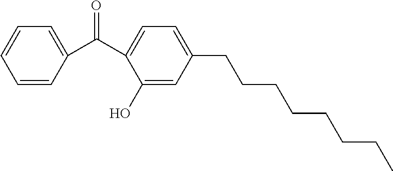 [SMILES: CCCCCCCCc1ccc(C(=O)c2ccccc2)c(O)c1] | 2, 3, 4, 5 |
| THT 1165 | 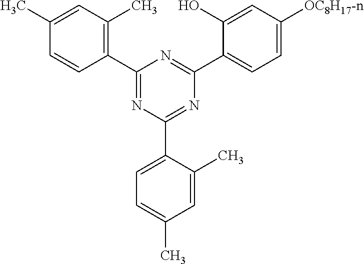 | 6 |

| | |
|---|---|
| Other Stabilizers Commercial Designation Weston 399 | Structure 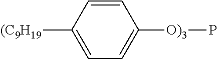 |

IRGAFOS 168

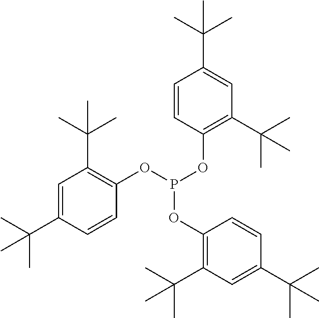 [SMILES: CC(C)(C)c1ccc(OP(Oc2ccc(C(C)(C)C)cc2C(C)(C)C)Oc2ccc(C(C)(C)C)cc2C(C)(C)C)c(C(C)(C)C)c1]

### Processing Conditions and Film Sample Preparation:

The film samples were prepared by mixing using Haake Polylab brand system with 60 rpm speed at 190° C. for 5 minutes followed by a quick cooling process and recovered as a slab about 3 mm thick. The compounded samples were cut into smaller squares of about 2.5 by 2.5 centimeters (cm) (1×1 inch) using New Hermes Shearer, placed between Mylar films in a mold and compressed as follows using a 15 mil (0.381 mm) spacer to provide a film having a thickness of 15 mil (0.381 mm) and a smooth final film surface. For the compression, the mold as described above was placed between Carver Compression Molders pre-heated to 190° C. The samples went through three compressions: 3,000 pounds (1362 kg) for 3 minutes; 10,000 pounds (4540 kg) for 3 minutes; and 20,000 pounds (9080 kg) for 2 minutes) followed by a quenching process under 3,000 pounds (1362 kg) pressure and ambient temperature for 3 minutes.

Light Transmission Measurement by UV-Vis

Using the UV-Vis spectrometer with scanning double monochromator and integrating sphere accessory, the Spectralon™ diffuse reflectance standards were mounted on both sample and reference ports of the Labsphere™ (model 60MM RSA ASSY) integrating sphere. The baseline correction was performed for the spectral range from 200-1200 nm with no sample in either the sample or reference entrance ports. The slit width and spectral resolution were 2 nm and the spectrum was acquired with 1 nm/point. The film sample was then mounted in the sample port at a 90 degree incidence angle to the sample beam. Multiple films were measured after the acquisition of the baseline correction after the instrument was initialized. The percentage transmission values at the 300 nm wavelength shown below in Table 3 for Films 1 through 19. The transmission percentages across the spectra range of 200 to 450 nm are shown in FIGS. 2a and 2 b where the figure number corresponds to the identification numbers shown in column 2 of Table 3.

TABLE 3
Light Stabilizer Transmission Evaluation

| | | | | | | | | Other | |
|---|---|---|---|---|---|---|---|---|---|
| Expt. | Fig. | Transmission | | | | | Other Light | Stabilizer | |
| No. | No. | at 300 nm | Absorber(s) | | HALS | | Stabilizers | Additives | |
| 1 | C 1 | 0.0 | | | | | | 399 | (1000) |
| 2 | C 3 | 0.0 | 531 | (3000) | 944 | (1000) | | | |
| | | | | | 622 | (1000) | | | |
| 3 | 10 | 0.3 | 531 | (3000) | 944 | (1000) | | | |
| | | | | | 622 | (1000) | | | |
| 4 | 11 | 2.0 | 531 | (3000) | 944 | (1000) | | 168 | (1200) |
| | | | | | 622 | (1000) | | | |
| 5 | C 2 | 4.5 | 531 | (3000) | 944 | (1000) | | 399 | (1000) |
| | | | | | 622 | (1000) | | | |
| 6 | 13 | 5.6 | THT1165 | (1000) | 3529 | (3000) | | 168 | (800) |
| | | | | | 3346 | (3000) | | | |
| 7 | 16 | 52.9 | | | 123 | (7000) | | 168 | (800) |
| 8 | 2 | 87.6 | | | 3529 | (3500) | | | |
| 9 | 7 | 85.8 | | | 3529 | (7000) | | | |
| 10 | 6 | 83.4 | | | 3529 | (10000) | | | |
| 11 | 12 | 66.9 | | | 3529 | (5000) | | 168 | (1200) |
| 12 | 1 | 79.6 | | | 3529 | (3500) | 2908 (3500) | | |
| 13 | 14 | 60.4 | | | 3529 | (3000) | | 168 | (800) |
| | | | | | 3346 | (2000) | | | |
| | | | | | 3853 | (2000) | | | |
| 14 | 8 | 89.3 | | | 4050 | (7000) | | | |
| 15 | 9 | 89.9 | | | N30 | (7000) | | | |
| 16 | 15 | 60.3 | | | 4050 | (3500) | | 168 | (800) |
| | | | | | 5050 | (3500) | | | |
| 17 | 3 | 83.6 | | | 119 | (7000) | | | |
| 18 | 4 | 86.9 | | | 944 | (7000) | | | |
| 19 | 5 | 87.4 | | | 622 | (7000) | | | |

As can be seen in FIGS. 2a and 2b, Films 7 through 19 in Table 3 transmit at least about 40 percent of the ultraviolet (UV) electromagnetic radiation having a wavelength in the UV range of from about 280 nm to about 380 nm.

### Experimental Film Samples 20-31

### Down-Conversion Effect in PV Devices

Additional films were prepared by the process as described above with and without down conversion materials for evaluation of their “down conversion” effectiveness as encapsulant layers in photovoltaic devices. The films were prepared from base resin formulations comprising the Silane-grafted ENGAGE 8200 resin and selected light stabilization components identified above along with the down conversion materials identified below in the amounts indicated in Tables 4 and 5:

### Down Conversion Additives:

Lumogen® F Yellow 083—(“L083”)—A perylene dye commercially available from BASF.

Lumogen® F Violet 570—(“L570”)—A naphthalimide dye commercially available from BASF.

Cell Performance Measurements

The prepared films were tested for their relative efficiencies in converting a standard illumination level into electric current, also referred to as their IV Characteristic Measurement. The device efficiency with the different films placed over the light collection aperture was obtained as a current-voltage (IV) characteristic curve that was measured using a Class AAA Solar simulator. The percentage efficiency (% Eff) is a standard figure of merit for solar cells, which is calculated as the maximum power generated by the solar cell (W) divided by the total solar irradiance (typically measured at 1000 W/m2) times the cell area (m2). All device figures of merit are based on total device area (rather than active device area).

TABLE 4
Cell Efficiency Results for CIGS PV Film

| | | | Light | | | |
|---|---|---|---|---|---|---|
| | Down | Down | Stabili- | | | |
| Film | Conversion | Conversion | zation | | T % at | % |
| No. | Additive 1 | Additive 2 | Additive | T % | 300 nm | Eff |
| 20 | | | | 92.4 | 85.00 | 6.46 |
| 21 | | | UV 531 | 91.8 | 0.03 | 6.4 |
| | | | 0.3% | | | |
| 22 | | | UV3529, | 92.4 | 78.00 | 6.5 |
| | | | 0.7% | | | |
| 23 | L570 | | | 93.3 | 86.00 | 6.44 |
| | 10 ppm | | | | | |
| 24 | L570 | | UV3529, | 92.4 | 79.00 | 6.67 |
| | 10 ppm | | 0.7% | | | |
| 25 | L570 | L083 | | 92.7 | 86.00 | 6.56 |
| | 1 ppm | 0.5 ppm | | | | |
| 26 | L570 | L083 | UV3529, | 92.3 | 83.00 | 6.63 |
| | 1 ppm | 0.5 ppm | 0.7% | | | |

TABLE 5
Cell Efficiency Results For Crystalline Silicon (c-Si) PV cells

| | Down | Light | | | |
|---|---|---|---|---|---|
| Film | Conversion | Stabilization | | T % at | |
| No. | Additive 1 | Additive | T % | 300 nm | % Eff |
| 27 | | | | 85 | 11.37 |
| 28 | | UV531, | | 0.03 | 11.03 |
| | | 3000 ppm | | | |
| 29 | | UV 3529 | | 78 | 11.18 |
| | | 7000 ppm | | | |
| 30 | L570 | | | 86 | 11.26 |
| | 10 ppm | | | | |
| 31 | L570 | UV 3529 | | 79 | 11.29 |
| | 10 ppm | 7000 ppm | | | |

Film samples 24, 26 and 31 show the combination of UV light stabilizers and down conversion materials could significantly improve efficiency of PV cell modules. Module efficiency test results show that films with down conversion materials have higher efficiency than film with UV absorbent.

Although the invention has been described in considerable detail through the preceding description, drawings and examples, this detail is for the purpose of illustration. One skilled in the art can make many variations and modifications without departing from the spirit and scope of the invention as described in the appended claims. All United States patents and published or allowed United States patent applications referenced above are incorporated herein by reference.

What is claimed is:

1. A thermoplastic resin formulation for use as a light transmitting layer in a photovoltaic module comprising:
(a) a light transmitting thermoplastic resin,
(b) at least one down conversion material that exhibits a maximum in incident radiation absorption in the range of 280 to 500 nm and a maximum in radiation emission at a relatively longer wavelength in the range of 400 to 900 nm and improves the efficiency of photovoltaic electric current generation in a photovoltaic module; and
(c) a light stabilizer additive that transmits at least about 40 percent of the ultraviolet (UV) electromagnetic radiation having a wavelength in the range of from about 280 nm to about 380 nm.

2. A thermoplastic resin formulation according to claim 1 wherein the down conversion material comprises exhibits a maximum in absorption of electromagnetic radiation within a spectral range from 300 to 500 nanometers.

3. A thermoplastic resin formulation according to claim 1 wherein the down conversion material exhibits a maximum in emission of electromagnetic radiation within a spectral range from 400 to 600 nanometers.

4. A thermoplastic resin formulation according to claim 1 wherein the down conversion material comprises a material selected from:
(a) inorganic nanoparticles selected from:
(i) nanoparticles of compounds containing photoluminescent lanthanide cations selected from the group consisting of: La, Ce, Pr, Eu, Nd, Pm, Sm, Tb, Dy, Ho, Er, Tm and Yb, and
(ii) quantum dots selected from the group of semiconductor nanocrystal compounds that can produce more than one excitons from one high energy photon of sunlight; and including composites comprising one or more of the nanoparticles (i) or semiconductor nanocrystal compounds (II) mentioned above having a core-shell structure, the nanoparticles or nanocrystals having a size range of from about 1 nm to about 200 nm; and
(b) organic luminescent down conversion additives selected from the following and including derivatives thereof: Rhodamine, Coumarin, Rubrene, Alq3, TPD, Gaq2Cl, Perylene dye, Naphthalene carbonic acid, and Violanthrone or iso-violanthrone.

5. A thermoplastic resin formulation according to claim 1 wherein the light stabilizer is selected from the group consisting of Cyasorb 3346, Cyasorb 3529; Chimassorb 944 LD; Tinuvin 622; Univul 4050; Univul 5050, also Hostavin N30 and Chimassorb 119.

6. A sheet material for use as a light transmitting layer in a photovoltaic cell comprising: thermoplastic resin formulation according to claim 1.

7. A photovoltaic module for the conversion of incident electromagnetic radiation into electric energy, comprising: (i) a light transmitting exterior surface cover sheet; (ii) at least one light transmitting encapsulation sheet material according to claim 6 providing protection to a photovoltaic cell from environmental effects, (iii) a protective exterior surface back sheet and (iv) least one photovoltaic cell adapted to convert into electric energy electromagnetic radiation that has passed through the cover sheet and encapsulation film.

8. The photovoltaic module according to claim 7, wherein the photovoltaic cell comprises at least one of the following materials: CdS; Si; CdTe; InP; GaAs; Cu₂S; and Copper Indium Gallium Diselenide (CIGS), Crystalline Silicon (c-Si), amorphous silicon or CIS.
